(19) United States
(12) Patent Application Publication
(10) Pub. No.: US 2004/0098646 A1
(43) Pub. Date: May 20, 2004

(54) Method and apparatus to check the integrity of scan chain connectivity by traversing the test logic of the device

(76) Inventor: Rory L. Fisher, Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/300,513

(22) Filed: Nov. 20, 2002

(51) Int. Cl. G01R 31/28

(52) U.S. Cl. 714/726

(57) ABSTRACT

An automated test method and apparatus are presented for checking the integrity of a scan chain. The automated test method implements a process that identifies specific configuration problems that are not discovered with conventional test procedures. The automated test method accesses a circuit such as an integrated circuit, which is represented as a network list of elements. The automated test method traverses the network list of elements in a forward direction and in a backward direction to identify configuration problems such as (1) a scan chain with multiple drivers; (2) multiple test signals associated with a scan chain (3) a broken scan chain; (4) a gated signal problem, and (5) a loop-back condition.

### BACKGROUND OF THE INVENTION

1. Field of the Invention

This invention relates to electronic systems. Specifically, the present invention relates to testing electronic systems.

2. Description of the Related Art

Modern electronic systems are often deployed on chips. The chips are used to implement Integrated Circuits such as Application Specific Integrated Circuits (ASIC). These integrated circuits include millions of active and passive digital components such as logical gates, memories, registers, etc. As such, millions of active and passive components are deployed on a chip. In addition, as electronic systems become more complex and miniaturization techniques develop, more components will be deployed on a single chip. For example, entire systems (i.e., system on a chip) are now deployed on one chip.

As the volume of components on a chip increase, the techniques for designing and integrating these components into circuits has advanced. In addition, the technology used to test the vast number of components has advanced. For example, software for designing and deploying integrated circuits is readily available today. In addition, testing methodologies, which group components together and isolate configuration problems, are commonly used in designing an integrated circuit.

A number of software techniques are available for designing integrated circuits. In one methodology, a software designer uses software that models the components in an integrated circuit design. As such, a designer is able to select and organize the components into a specific integrated circuit design using the software. Each component is represented by a label or title. When the labels or titles are combined to represent an integrated circuit, the list of labels or titles associated with the components are referred to as a netlist (i.e., network list of components).

In addition to the methodologies used to design integrated circuits, methodologies have developed for testing integrated circuits. For example, since there are a large number of components included in these integrated circuits, techniques have developed which group the components together for testing. As such, a group of components may be tested and problems can be isolated to a specific component. Testing a group of components in this way, results in shorter design and deployment cycles.

One example of a conventional process used for testing integrated circuits is known as a scan chain test. During a scan chain test, components are linked in series (i.e., scan chain) and a test signal known as a test vector (i.e., serial data) is communicated through the scan chain. The input to the scan chain is tested against the output of the scan chain to ensure that the components in the scan chain are configured properly.

In order to perform a scan chain test, circuitry is added to the standard logic of an integrated circuit. At a minimum, this includes hardware known as a Test Access Port (TAP) Controller to control the scan chain operation. The Test Access Port Controller receives a test clock (TCK) for providing timing information and a test mode select (TMS) for selecting a test mode of operation. In addition, access points are connected between the integrated circuit and the Test Access Port Controller. One access point known as a “SIN” (i.e., scan in) port is used to transmit a serial data stream to the scan chain. Another access point known as a “SOUT” (i.e., scan out) port receives a serial data stream from the scan chain.

One conventional scan test is an external test. In an external test, data is scanned into the device (i.e., scan chain) serially, clocked around the scan chain, and then communicated from the output of the scan chain. This data is a test vector; the test vector (i.e., 0's and 1's) is formatted into a serial data stream that is sent from the TAP Controller through the scan chain and back to the TAP Controller.

An internal test can be used to test the core logic of the integrated circuit. The internal test has two parts. During the first part of the internal test, a sequence of instructions is activated. An internal self-test is performed and after a prescribed number of clock cycles, the results are scanned out of the scan chain to the SOUT port on the TAP Controller for verification. In the second part of the internal test, a static test pattern is entered into the device through the scan chain, the static test pattern is applied to the core logic, and the resultant pattern shifted out to the SOUT port of the TAP Controller for analysis.

However, conventional testing methodologies are flawed. While the testing methodologies may uncover many of the common or basic problems, there is a class of configuration problems that conventional testing methodology do not recognize. For example, since most testing methodologies depend on generating a test vector (i.e., pattern) and then analyzing the test vector (i.e., pattern), any network configuration problems that produce the expected test stream will be overlooked by most testing methodologies.

Thus, there is a need to identify the configuration problems that are not recognized by conventional testing methodologies. There is a need in the art for testing methodologies that identify configuration problems that pass the conventional testing methodologies.

### SUMMARY OF THE INVENTION

An automated test methodology is presented. A method and apparatus for testing an integrated circuit for configuration problems is presented. In one embodiment of the present invention, the automated test methodology is implemented as a computer program. As part of the test methodology, specific configuration problems or categories of configuration problems are identified for analysis. The automated test methodology is then implemented to analyze the integrated circuit and identify the configuration problems.

In one method of the present invention, a test method comprises the steps of accessing a network list of elements, the network list of elements represents a circuit; the method traverses the circuit in a forward direction by traversing the network list of elements; traverses the circuit in a backward direction by traversing the network list of elements; and identifies a scan chain with multiple drivers in response to traversing the circuit in the forward direction and in response to traversing the circuit in the backward direction.

A test method comprises the steps of accessing a network list of elements, the network list of elements represents a circuit; the method traverses the circuit in a forward direction by traversing the network list of elements; traverses the circuit in a backward direction by traversing the network list of elements; and identifies multiple test signals associated with a scan chain in response to traversing the circuit in the forward direction and in response to traversing the circuit in the backward direction.

A test method comprises the steps of accessing a network list of elements; the network list of elements represents a circuit; the method traverses the circuit in a forward direction by traversing the network list of elements; traverses the circuit in a backward direction by traversing the network list of elements; and identifies a broken scan chain in response to traversing the circuit in the forward direction and in response to traversing the circuit in the backward direction.

A test method comprises the steps of accessing a network list of elements, the network list of elements represents a circuit; the method traverses the circuit in a forward direction by traversing the network list of elements; traverses the circuit in a backward direction by traversing the network list of elements; and identifies a gated test signal in response to traversing the circuit in the forward direction and in response to traversing the circuit in the backward direction.

A test method comprises the steps of accessing a network list of elements, the network list of elements represents a circuit; the method traverses the circuit in a forward direction by traversing the network list of elements; traverses the circuit in a backward direction by traversing the network list of elements; and identifies a feedback loop in response to traversing the circuit in the forward direction and in response to traversing the circuit in the backward direction.

A test method comprises accessing an integrated circuit design represented as a network list of elements, the integrated circuit design comprising a controller including a port communicating with registers using a data stream; identifying the controller from the network list of elements; identifying the port driven by the test controller; traversing the network list of elements; generating a table of configuration information in response to traversing the network list of elements; and identifying a configuration problem by querying the table of configuration information.

Performing the method of the present invention connectivity conditions (i.e., configuration problems), which would go undetected using conventional methods, can be detected very early in the design process. As soon as a netlist of the integrated circuit is available, the automated test methodology of the present invention (i.e., automated test program) may be run on building block components of an integrated circuit (i.e., portions of the netlist) to detect design errors.

### BRIEF DESCRIPTION OF THE DRAWINGS

FIG. 1 displays an implementation of a flip-flop.

FIG. 2 displays a scan chain with multiple drivers.

FIG. 3 displays a scan chain with multiple test signals associated with the scan chain.

FIG. 4 displays a scan chain with gated test signals.

FIG. 5 displays a scan chain including a feedback loop.

FIG. 6 displays a multi-function computer implementing an automated test procedure in accordance with a method of the present invention.

FIG. 7 displays a flow chart implementing a method of the present invention.

### DESCRIPTION OF THE INVENTION

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

In one embodiment of the present invention, a test methodology is presented. The test methodology may be applied to a circuit, for example, an integrated circuit. The test methodology may be applied to a circuit, which is represented in computer software, such as Computer Aided Design (CAD) software. However, it should be appreciated that the test methodology may be applied to any electronic system.

When the test methodology of the present invention is used to analyze circuits represented in computer software, the test methodology may be implemented as computer instructions that automate the analysis of the circuits. As such, the test methodology may be considered an automated test methodology.

Circuit design software typically includes a plurality of circuit elements, each referred to as a “cell.” For example, a cell may include both active and passive elements such as logical gates, registers, buffers, flip-flops, etc. The circuit design software may also maintain the connections between the cells. The connections are often referred to as “nets.” Therefore, the cells and nets combine to represent the integrated circuit (i.e., ASIC, microprocessor, etc.) in the circuit design software.

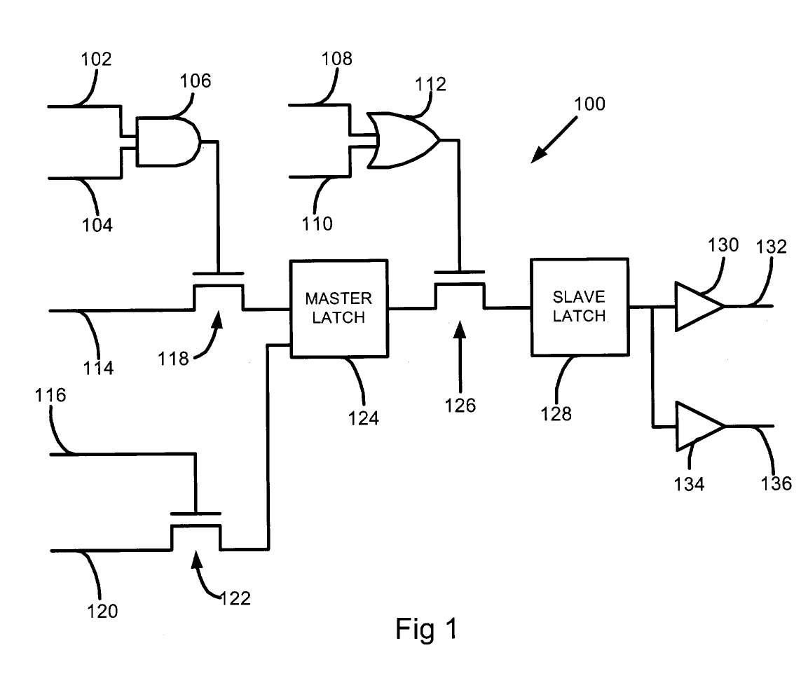

FIG. 1 is a flip-flop 100 implementing the teachings of the present invention. In one embodiment of the flip-flop 100, a clock signal 108 and a shift_slave signal 110 provide input to an OR gate 112. A NORM signal 104 and a compliment of the clock signal 102 provide input to an AND gate 106. A D-input 114, a shift_master signal 116 and a Scan_in signal 120 (i.e., serial data input) are toggled by gates 118 and 122 and provide input to a master latch 124. A gate 126 is connected to the master latch 124 and the OR gate 112. The gate 126 toggles the input to a slave latch 128. The output of the slave latch 128 is buffered at 130 and produces a Q output 132 or buffered at 134 to produce a Scan_out signal 136 (i.e., serial data output). During normal operation (i.e., non-test operation), the NORM signal 104 is held high (i.e., logical 1), the shift_slave signal 110 is held low (i.e., logical 0), and the shift_master signal 116 is also held low (i.e., logical 0). When the clock signal 108 is high, the clock signal 108 enables data transfer between the master latch 124 and the slave latch 128, which are storage nodes. During operation, the clock signal 108 can be used to bring data into the flip-flop 100 and transfer data out of the flip-flop 100. For example, when the clock signal 108 is low, data is transferred from the D input 114 to the master latch 124.

Several flip-flops 100 may be connected in series to form a scan chain for testing. For example, during test operation, data is shifted into the master latch 124, through the gate 122, using the Scan_in signal 120. When flip-flops 100 are connected in series, the Scan_out signal 136 is connected in series to the Scan_in signal 120 of a previous flip-flop in the scan chain of flip-flops. As a result, data is transferred through the flip-flops serially. In normal operation, the Q output 132 is used to connect to another logical device such as another register or combinational logic. It should be appreciated that, although a specific flip-flop 100 has been presented, there are a number of different types of flip-flops 100 or logical devices that are within the scope of the present invention.

As shown in FIG. 1, the Scan_in signal 120 is a serial data stream that is scanned into a scan chain during test operations. The Scan_out signal 136 is a serial data stream that is scanned out of a scan chain during test operations. The shift_slave signal 110 causes the slave latch 128 to shift data. The shift_master signal 116 causes the master latch 124 to shift data. The NORM signal 104 is used to distinguish between normal operation and test operation. In one embodiment of the present invention, the NORM signal 104 is set high during normal operation and set low during test operations.

The flip-flop 100 shown in FIG. 1 may reside in a single device such as a register. For the purposes of discussion a number of conventions will be implemented. The port on the Test Access Port (TAP) Controller that generates a serial data stream for testing is identified as a SIN port in the disclosure and drawings. The port on TAP Controller that receives a serial data stream from the scan chain is identified as a SOUT port in the disclosure and drawings. The port on the TAP Controller that generates the shift_master signal 116 is referred to as the shift_master port. The port on the TAP Controller that generates the shift_slave signal 110 is referred to as the shift_slave port. The port on the TAP Controller that generates the NORM signal 104 is referred to as the NORM port. The port on a register that receives a serial data stream for testing is identified as a SIN port in the disclosure and drawings. The port on a register that transmits a serial data stream is identified as a SOUT port in the disclosure and drawings.

As integrated circuits are combined into different configurations, specific classes of configuration problems result. In the method and apparatus of the present invention, configuration problems are identified by using the automated test methodology of the present invention. Identifying these key configuration problems can significantly reduce cycle times for design and deployment of integrated circuit based technology.

The methodology of the present invention identifies several classes of configuration problems. The first configuration problem is a scan chain has multiple drivers. The second configuration problem occurs when multiple test signals are associated with a scan chain. The third configuration problem is a gated test signal. The fourth configuration problem is a loop-back configuration. A fifth configuration problem is a broken scan chain. These configuration problems may occur because of operator error, because of problems in automated programs that configure integrated circuits or for a myriad of other reasons.

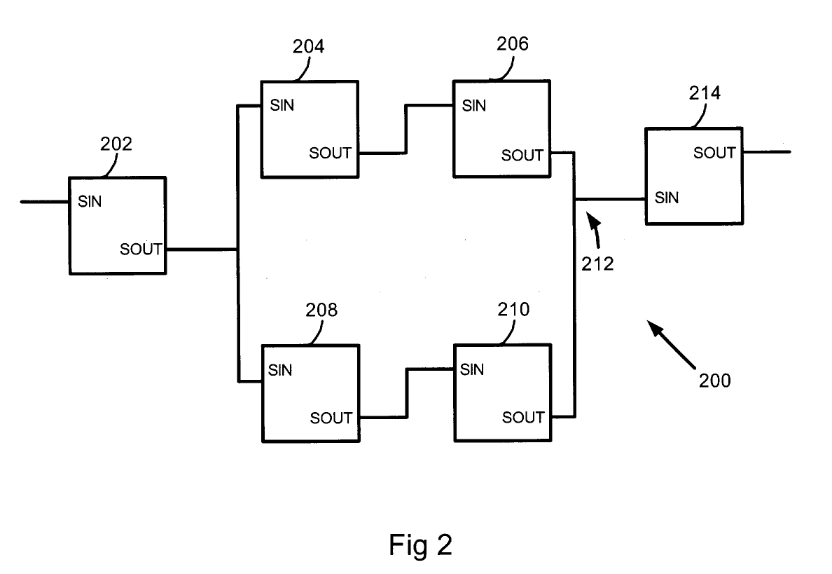

FIG. 2 displays a configuration problem, which involves a scan chain with multiple drivers. In FIG. 2, registers 202, 204, 206, 208, 210 and 214 are shown. Registers 208 and 210 are configured in parallel with registers 204 and 206. Registers 202, 204, 206 and 214 form a scan chain. Therefore, registers 208 and 210 are connected in parallel with the scan chain.

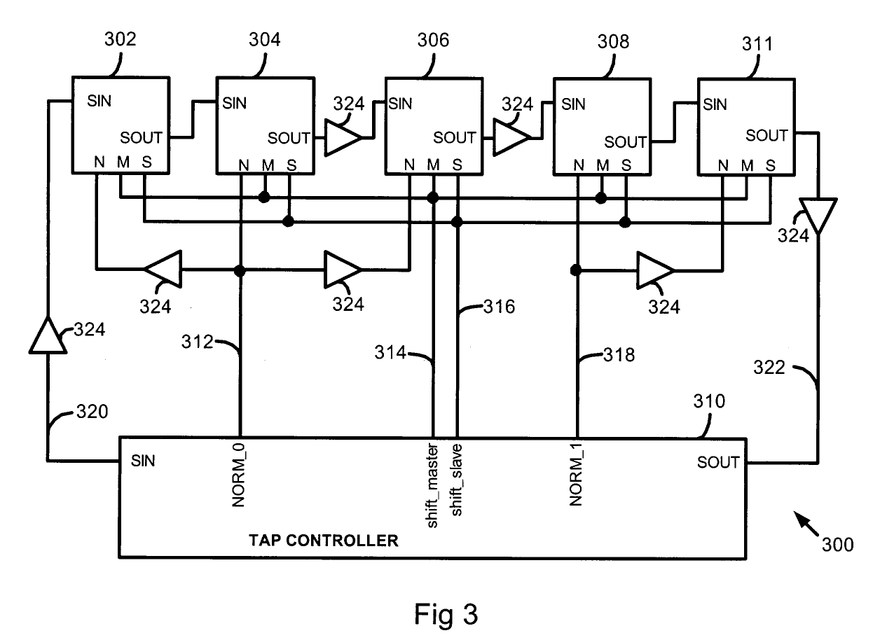

In the configuration of FIG. 2, the data going into the bottom two registers 208 and 210 is identical to the data going into the top two registers 204 and 206. The data coming out of register 202 would provide the same input into registers 204 and 208, which in turn would cause the same output to result from registers 206 and 210. Since the same data would result at a point (i.e., net) denoted by 212, most software testing programs, which input data (i.e., a test vector) and then test for the data at an output, would not detect this configuration problem. In addition, if there is a defect that shorts the net denoted by 212 to a power supply or ground, a drive fight would result at the point denoted by 212. A drive fight would result if one of the registers was trying to drive a value, which was opposite to the value that the net was shorted to. For example, if the net denoted by 212 was shorted to a power supply and the registers 206 and 210 were trying to output a logical 0 at the point denoted by 212, a drive fight would result. In the alternative, if the net denoted by 212 was shorted to ground and the registers 206 and 210 were trying to output a logical 1 at the point denoted by 212, a drive fight would result. FIG. 3 displays a configuration problem 300 in which multiple test signals are associated with a scan chain. In FIG. 3, five registers (302, 304, 306, 308, 311) are connected serially to form a scan chain. The five registers form a five-bit scan chain. In addition, a Tap Controller 310 communicates serial data 320 from a SIN port and receives serial data 322 through a SOUT port. It should be noted that the serial data 320 is communicated from the TAP Controller 310 (i.e., SIN port) to the scan chain (e.g., registers 302, 304, 306, 308, 311) during testing. The serial data 322 is scanned out of the scan chain (e.g., registers 302, 304, 306, 308, 311) and into the SOUT port of the TAP Controller 310 during testing. In addition, each of the five registers receives a NORM signal (N), a shift_master (M) signal and a shift_slave (S) signal. The shift_master (M) signal and the shift_slave (S) signal are shown as 314 and 316, respectively.

FIG. 3 displays a scenario where there are multiple test signals associated with a scan chain. In FIG. 3, there are multiple NORM signals that are associated with the same scan chain (e.g., 302, 304, 306, 308 and 311). A first NORM signal 312 (i.e., NORM_{—}0) is input to registers 302, 304 and 306. A second NORM signal 318 serves as direct input to register 308 and passes through one of the buffers 324 to serve as input to register 311.

A NORM signal is typically associated with a single clock domain. When there are two NORM signals, they are each associated with different clock domains. For example, the first NORM signal 312 is associated with one clock domain and the second NORM signal 318 is associated with a different clock domain. As a result, two different signals (i.e., NORM_{—}0 and NORM_{—}1) are applied to various registers in the scan chain, which would cause the scan chain to malfunction. For example, to scan data out of a scan chain the NORM signal should be held high. However, suppose that the first NORM signal 312 (i.e., NORM_{—}0) is held low while the second NORM signal 318 (i.e., NORM_{—}1) is held high. This scan test will not function properly because the first NORM signal 312 is held low while the second NORM signal 318 is held high and that will prevent the scan chain from shifting data.

Another configuration problem identified and addressed in the method and apparatus of the present invention is a broken scan chain problem. A broken scan chain would occur when there is a disconnection anywhere in the scan chain. For example, in FIG. 3, if the serial data 322 is communicated on a disconnected wire, the serial data 322 would not get back to the Tap Controller 310 (i.e., SOUT port).

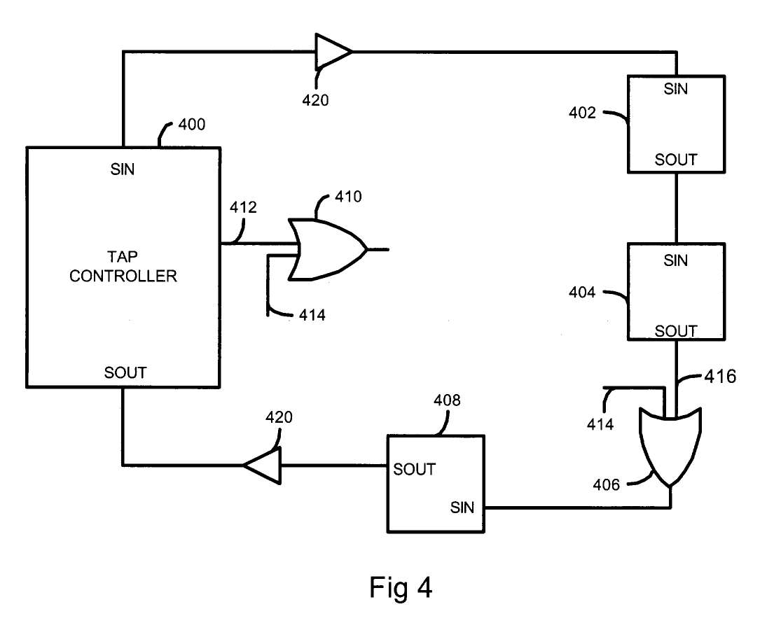

FIG. 4 displays a configuration scenario in which various signals are gated. FIG. 4 displays a Tap Controller 400 and three registers 402, 404 and 408 configured in a scan chain. An OR gate 410 receives a NORM signal 412 and a reset signal 414 as inputs. An OR gate 406 receives a serial data stream 416 and a reset signal 414 as inputs. In addition, buffers are shown as 420.

Two configuration problems are demonstrated using the circuit displayed in FIG. 4. First a NORM signal 412 transmitted from the Tap Controller 400 is gated with a second signal (i.e., reset signal 414). Second, an OR gate 406 is interjected in the scan chain and a reset signal 414 is gated with a serial data stream 416.

When a NORM signal 412 is gated prior to the connection to a register, a problem occurs in shifting data through the scan chain. For example, if a serial test is run when the reset signal 414 is held high, it is required that the NORM signal 412 is held low. However, the reset signal 414 will force the output of the OR gate 410 to be held high. Therefore, data would not shift through the scan chain when reset is held high. In a similar manner, when the serial data stream 416 is gated through the scan chain, a similar problem occurs. If the reset signal 414 is held high, it distorts any data that is processed through the OR gate 406 because once the reset signal 414 is held high, the output of the OR gate 406 would always be held high.

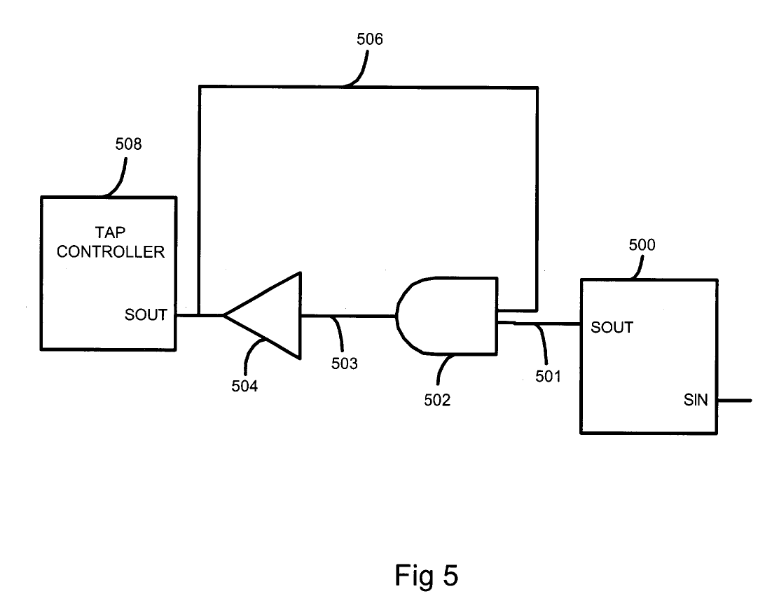

FIG. 5 displays another configuration problem identified and addressed by the methodology of the present invention. FIG. 5 displays a loop-back configuration problem. A serial data stream (i.e., 501) is generated from a register 500 and serves as input to an AND gate 502. The AND gate 502 produces an output (i.e., 503) that serves as an input for the buffer 504. The output of the buffer 504 is input into the Tap Controller 508 (i.e., SOUT port).

A loop-back is shown as 506. The loop-back 506 takes the output from the buffer 504 and feeds the output back into the AND gate 502. As the data on the loop-back 506 is fed back into the AND gate 502, the data coming out of the AND gate 502 may be corrupted on the output shown as 503.

In accordance with one method of the present invention, an automated test methodology to identify the various classes of configuration problems identified above is discussed. The automated test method may be implemented in a multi-function computer as computer instructions. The automated test methodology detects: (1) a scan chain with multiple drivers; (2) when multiple test signals are associated with a scan chain; (3) broken scan chains; (4) various gated signal problems; and (5) a loop-back configuration.

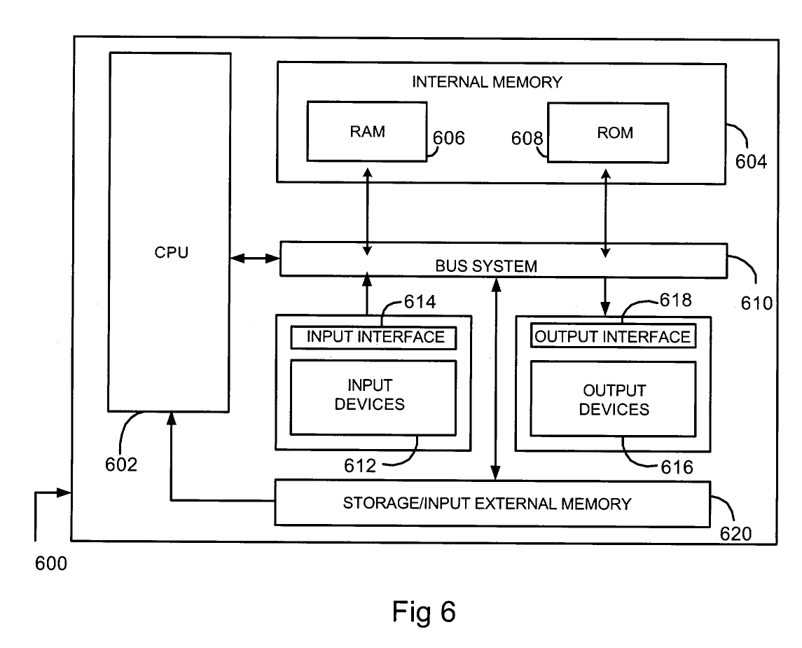

The automated test method implemented in accordance with the present invention may be implemented using a multi-function computer. FIG. 6 is a block diagram of a multi-function computer 600 implementing the present invention. In FIG. 6, a central processing unit (CPU) 602 performs centralized control of the multi-function computer 600. Internal memory 604 is shown. The internal memory 604 includes short-term memory 606 and long-term memory 608. The short-term memory 606 may be Random Access Memory (RAM) or a memory cache used for staging information. The long-term memory 608 may be a Read Only Memory (ROM) or an alternative form of memory used for storing information. A bus system 610 is used by the CPU 602 to control the access and retrieval of information from short-term memory 606 and long-term memory 608.

Input devices such as joystick, keyboards, microphone or a mouse are shown as 612. The input devices 612 interface with the system through an input interface 614. Output devices such as a monitor, speakers, etc. are shown as 616. The output devices 616 interface with the multi-function computer 600 through an output interface 618. External memory such as a hard drive is shown as 620. The bus system 610 may communicate with output ports, which communicate information out of the multi-function computer 600. The information may be communicated from the bus system 610, through an interface (not shown), and across a Local Area Network or across a Wide Area Network.

The method and apparatus of the present invention may be implemented in a stand-alone architecture. In addition, the method and apparatus of the present invention may be implemented in a networked computer. When implemented in a networked computer, the method and apparatus of the present invention may be implemented in a Local Area Network, a Wide Area Network, across a distributed network, or in a client-server architecture.

In one embodiment, computer instructions are used to implement the method of the present invention. The computer instructions may be implemented in higher-level computer languages or lower-level computer languages. The computer instructions may be implemented using general-purpose computer languages or proprietary computer languages. For example, the method of the present invention may be implemented using computer instructions from the JAVA language or the C++ computer language. The computer instructions may be stored in RAM 606, ROM 608 or in the external memory 620 (i.e., hard drive). In one embodiment of the present invention, the computer instructions are stored in the external memory 620, the RAM 606 or hard coded in the ROM 608 and instruct the CPU 602 to access and process data (e.g., such as net-list).

In one embodiment of the present invention, a table of configuration information is compiled as a circuit is traversed in the forward and backward direction. The table may be stored in a database. As such, the database may be stored in a memory such as external memory 620, RAM 606 or a networked connected via a network connection. The database of configuration information (i.e., table) may be queried using computer instructions from a general-purpose computer language or proprietary query instructions associated with a third party database.

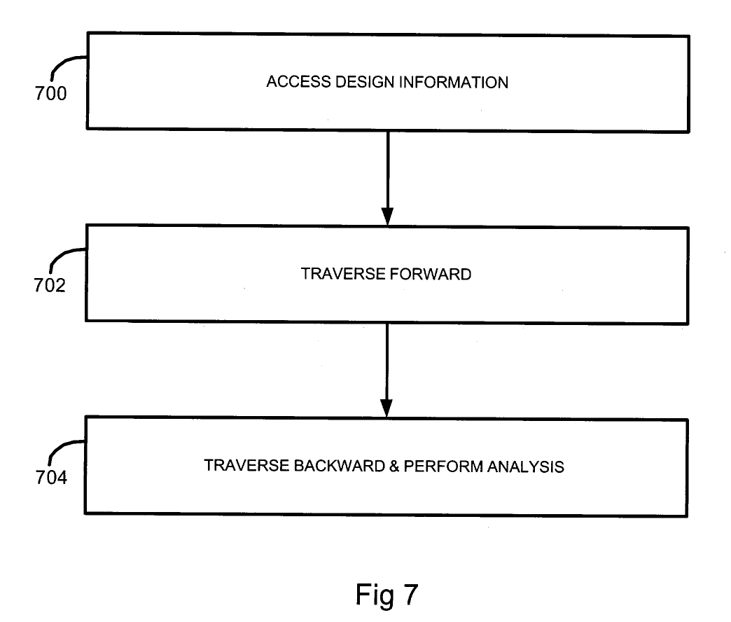

FIG. 7 displays a flow chart of one method of the present invention. The method may be implemented in software as computer instructions to perform automated testing. The method is used to identify various configuration problem in an integrated circuit design such as (1) a scan chain with multiple drivers; (2) multiple test signals associated with a scan chain; (3) broken scan chains; (4) various gated signals problems; and (5) loop-back configurations.

A flow diagram shown in FIG. 7, displays an automated test method. In the first step of the method shown as 700, circuit information is accessed. The circuit information is information that characterizes the circuit under analysis. The circuit information may be text information detailing a circuit design, Computer Aided Design (CAD) drawings identifying a circuit design, etc. The circuit information may be stored in a storage device in a computer running the automated test method or the circuit information may be stored and accessed from across a network.

In one embodiment of the present invention, the circuit information characterizes an integrated circuit. The integrated circuit is represented in computer software by a netlist. The netlist represents the components of the integrated circuit. Each of the components are labeled and uniquely identified in the netlist. In addition, the netlist defines the relationship and connections between the components of the integrated circuit. Lastly, the netlist may be structured as a layered listing to correspond to the layered architecture of the integrated circuit. For example, each register 202, 204, 206, 208, 210, and 214 of FIG. 2 may be structured as shown by flip-flop 100 of FIG. 1. The netlist is defined in a manner that is consistent with the device hierarchy.

Groups of components or portions of the integrated circuit are referred to as a block. A block may be a sub-group in a hierarchy of groups or a block may be a group of components in the integrated circuit.

An automated test method in accordance with the teachings of the present invention reads the netlist into memory for processing. In an alternative embodiment, the automated test method may read a portion of the netlist into memory for processing. The automated test method traverses the hierarchy of the integrated circuit to find the Tap Controller. The Tap Controller may be identified with a specific label such as “TAP” or “TAP=TRUE.”

In an alternate embodiment of the present invention, there is no Tap Controller and the automated test method traverses the netlist to find an input port to the scan chain by identifying a predefined label given to the input port. In another embodiment of the present invention, the automated test method is run on blocks as they are constructed (i.e., in the software), rather than waiting for the completion of the entire integrated circuit design.

Once the design information is accessed, the automated test method traverses the integrated circuit (i.e., via the netlist) in a forward direction as shown at 702. In one embodiment of the present invention, the forward traversal 702 is defined relative to the Tap Controller. In another embodiment of the present invention, the forward traversal 702 may be any agreed upon direction. Alternatively, the forward traversal 702 may be defined relative to an element or group of elements. The forward traversal 702 may be defined from the input of a cell to the output of a cell or from the input of the scan chain to the output of the scan chain. Lastly, the forward traversal 702 may be defined from the SIN port to the SOUT port.

To traverse in the forward direction the automated test method begins from the Tap Controller, which was detected in the previous step. The automated test method then searches through the netlist to find all the NORM ports (i.e., ports on the Tap Controller driving the NORM signal). For example, using FIG. 3, the Tap Controller would identify NORM_{—}0 shown as 312 and NORM_{—}1 shown as 318.

After identifying each NORM port, the automated test method traverses each logic component in a forward direction through the combinational logic (e.g., buffers, inverters, gates, etc.) beginning from the NORM port. The automated test method stops traversing when it reaches a storage element such as a register or latch element. The label of each encountered storage element is stored in a table and associated with the NORM port that was traversed to reach the storage element. For example, the registers associated with the first NORM signal 312 (i.e., NORM_{—}0) are registers 302, 304, and 306. The registers associated with the second NORM signal 318 (i.e., NORM_{—}1) are registers 308 and 311. Each of the registers would be stored in a table and correlated with the appropriate NORM signal.

The table may store configuration information. The table may be implemented as a database, a spreadsheet or a flat file. The table may correlate a number of different types of configuration information. For example, the table may correlate signals to register, signals to logic gates, ports to registers, ports to logic gates. It should be appreciated that any configuration information that correlates components (i.e., including signals) of the integrated circuit to other components of the integrated circuit may be considered configuration information, which is stored in the table.

The table may be queried using computer instructions implemented in accordance with the teachings of the present invention. In addition, if the table is store in a database such as a third party database, the table may be queried using the native language of the third party database.

The automated test method then identifies the ports on the Tap Controller that generate the shift_master and shift_slave signals. For example, using FIG. 3 shift_master signal 314 and shift_slave signal 316 are identified. A similar traversal of the logic is performed using the shift_master signal 314 and the shift_slave signal 316. Tables are also used to store the relationship between the ports on the Tap Controller and the registers that are encountered while performing the traversal. For example, using FIG. 3, when a traversal is made using the shift_master port 314, each of the registers 302, 304, 306, 308 and 311 are encountered. When a traversal is made using the shift_slave port 316, each of the registers 302, 304, 306, 308 and 311 are encountered. Therefore, a table is produced which shows an association between the shift_master signal 314 and each register 302, 304, 306, 308 and 311, and the shift_slave signal 316 and each register 302, 304, 306, 308, and 311.

While traversing the NORM signals 312 and 318, the shift_master signal 314 and the shift_slave signal 316, if a non-register logic component is encountered which has more than one non-power input port, the non-register logic component is identified by the automated test method as a “test signal gater” (i.e., a gate that receives a test signal as an input) and a warning is issued. In the alternative, while traversing the NORM signal, if an AND gate or an OR gate is encountered and all of the inputs of the AND gate or the OR gate are tied together, no warning is issued. If all the inputs of an inverting component (i.e., NAND gate or NOR gate) are tied together, a warning is issued.

For example, using FIG. 4, OR gates 406 and 410 are non-register logical components. In the case of OR gate 406, a serial data stream 416 and reset signal 414 are inputs to OR gate 406. Since the serial data stream 416 is an input to the OR gate 406, the OR gate 406 is a test signal gater. In the case of OR gate 410, NORM signal 412 and RESET signal 414 serve as inputs to OR gate 410. OR gate 410 would be considered a test signal gater because OR gate 410 has a test signal (i.e. NORM signal 412) as an input.

After traversing in the forward direction 702, the automated test method traverses the network in a backward direction as shown at 704. In addition, analysis is made of the network information to determine any configuration issues that may be present.

During the backward phase of the process 704, all of the SOUT ports and signals of the registers in the integrated circuit are identified. For example, using FIG. 3, registers 302, 304, 306, 308 and 311 are identified. Each SOUT port or register is traversed in the backward direction 704 until a success condition, a loop-back condition, or a dead-end condition is met.

A success condition signifies that a SOUT port on the TAP Controller has been reached, meaning that the automated test method was able to traverse the integrated circuit all the way back to the TAP Controller.

A loop-back condition indicates that a loop-back configuration problem has been detected. Traversing backward from the SOUT port of the Tap Controller 508, the loop-back 506 is encountered. Buffer 504 is identified as the driver of the loop-back 506. Output 503 (i.e., network link 503) is identified as the driver of buffer 504. AND gate 502 is identified as the driver of output (i.e., network link) 503. Loop-back 506 and the serial data stream 501 drive AND gate 502. This signals a loop-back condition in the automated test method because loop-back 506 was already encountered and traversed.

A dead end indicates a broken scan chain. For example, if during the backward traversal process 704, the automated test method runs out of elements to traverse and the automated test method has not reached the Tap Controller, a dead end is identified.

Each time a register is encountered while traversing the scan chain, the NORM, shift_master and shift_slave tables (i.e., tables generated while traversing these signals) are queried with the name of the encountered register to confirm that only one entry exist for the register. For example, when register 311 is encountered during the traversal, the tables indicate that register 311 is associated with the second NORM signal 318, the shift_master signal 314 and the shift_slave signal 316. If there are zero entries or multiple entries associated with a given register, an error condition is reported.

While traversing the scan chain in a backward direction 704 (i.e., starting with the SOUT port of the Tap Controller), if a non-register element is encountered with multiple non-power inputs, the cell is identified as a test signal gater and a warning is issued. In the alternative, if the element is an AND gate or an OR gate and all the inputs of the cell are tied together, no warning is issued.

While traversing backward 704 (i.e., from SOUT port to SIN port), a test is also made to determine if there is more than one cell trying to drive a specific net. For example, using FIG. 2, traversing backward from register 214 there is more than one cell such as registers 206 and 210 that are driving a specific net such as 212.

After a scan chain has been successfully traversed back to the Tap Controller, the number of NORM, shift_master and shift_slave signals associated with the entire chain is calculated. If the program determines that zero or multiple NORM, shift_master or shift_slave signals are associated with a given scan chain, a warning is issued. For example, in FIG. 3, a warning will be issued after traversing backward (i.e., from the SOUT port) since both the first NORM signal 312 and the second NORM signal 318 are associated with the scan chain.

Thus, the present invention has been described herein with reference to a particular embodiment for a particular application. Those having ordinary skill in the art and access to the present teachings will recognize additional modifications, applications and embodiments within the scope thereof.

It is, therefore, intended by the appended claims to cover any and all such applications, modifications and embodiments within the scope of the present invention.

What is claimed is:

1. A test method comprising the steps of:
accessing a network list of elements, the network list of elements representing a circuit;
traversing the circuit in a forward direction by traversing the network list of elements;
traversing the circuit in a backward direction by traversing the network list of elements; and
identifying a scan chain with multiple drivers in response to traversing the circuit in the forward direction and in response to traversing the circuit in the backward direction.

2. A test method comprising the steps of:
accessing a network list of elements, the network list of elements representing a circuit;
traversing the circuit in a forward direction by traversing the network list of elements;
traversing the circuit in a backward direction by traversing the network list of elements; and
identifying multiple test signals associated with a scan chain in response to traversing the circuit in the forward direction and in response to traversing the circuit in the backward direction.

3. A test method comprising the steps of:
accessing a network list of elements, the network list of elements representing a circuit;
traversing the circuit in a forward direction by traversing the network list of elements;
traversing the circuit in a backward direction by traversing the network list of elements; and
identifying a broken scan chain in response to traversing the circuit in the forward direction and in response to traversing the circuit in the backward direction.

4. A test method comprising the steps of:
accessing a network list of elements, the network list of elements representing a circuit;
traversing the circuit in a forward direction by traversing the network list of elements;
traversing the circuit in a backward direction by traversing the network list of elements; and
identifying a gated test signal in response to traversing the circuit in the forward direction and in response to traversing the circuit in the backward direction.

5. A test method comprising the steps of:
accessing a network list of elements, the network list of elements representing a circuit;
traversing the circuit in a forward direction by traversing the network list of elements;
traversing the circuit in a backward direction by traversing the network list of elements; and
identifying a feedback loop in response to traversing the circuit in the forward direction and in response to traversing the circuit in the backward direction.

6. A test method comprising:
accessing an integrated circuit represented as a network list of elements, the integrated circuit comprising a controller including a port;
identifying the controller in the network list of elements;
identifying the port on the controller driving a signal;
traversing the network list of elements by following the signal;
generating a table of configuration information in response to traversing the network list of elements; and
identifying a configuration problem by querying the table of configuration information.

7. A test method as set forth in claim 6, wherein the step of traversing the network list of elements is performed in the forward direction.

8. A test method as set forth in claim 6, wherein the step of traversing the network list of elements is performed in the backward direction.

9. A test method as set forth in claim 6, wherein communicating a data stream includes transmitting the data stream.

10. A test method as set forth in claim 6, wherein communicating a data stream includes receiving the data stream.

11. A test method as set forth in claim 6, wherein the port is a NORM port and the signal is a NORM signal.

12. A test method as set forth in claim 6, wherein the port is a shift_master port and the signal is a shift_master signal.

13. A test method as set forth in claim 6, wherein the port is a shift_slave port and the signal is a shift_slave signal.

14. A test method as set forth in claim 6, wherein the test controller is a TAP controller.

15. A test method as set forth in claim 6, wherein the configuration problem is a scan chain with multiple drivers.

16. A test method as set forth in claim 6, wherein the configuration problem includes multiple test signals associated with a scan chain.

17. A test method as set forth in claim 6, wherein the configuration problem is a broken scan chain.

18. A test method as set forth in claim 6, wherein the configuration problem is a gated signal.

19. A test method as set forth in claim 6, wherein the configuration problem is a feedback loop.

20. A test method as set forth in claim 6, wherein the configuration information includes information correlating the signal to the register.

21. A test method as set forth in claim 6, wherein the configuration information includes information correlating the port to a register.

22. A test system comprising:
means for accessing a network list of elements, the network list of elements representing a circuit;
means for traversing the circuit in a forward direction by traversing the network list of elements;
means for traversing the circuit in a backward direction by traversing the network list of elements; and
means for identifying a scan chain with multiple drivers in response to traversing the circuit in the forward direction and in response to traversing the circuit in the backward direction.

23. A test system comprising:
means for accessing a network list of elements, the network list of elements representing a circuit;
means for traversing the circuit in a forward direction by traversing the network list of elements;
means for traversing the circuit in a backward direction by traversing the network list of elements; and
means for identifying multiple test signals associated with a scan chain in response to traversing the circuit in the forward direction and in response to traversing the circuit in the backward direction.

24. A test system comprising:
means for accessing a network list of elements, the network list of elements representing a circuit;
means for traversing the circuit in a forward direction by traversing the network list of elements;
means for traversing the circuit in a backward direction by traversing the network list of elements; and
means for identifying a broken scan chain in response to traversing the circuit in the forward direction and in response to traversing the circuit in the backward direction.

25. A test system comprising:
means for accessing a network list of elements, the network list of elements representing a circuit;
means for traversing the circuit in a forward direction by traversing the network list of elements;
means for traversing the circuit in a backward direction by traversing the network list of elements; and
means for identifying a gated test signal in response to traversing the circuit in the forward direction and in response to traversing the circuit in the backward direction.

26. A test system comprising:
means for accessing a network list of elements, the network list of elements representing a circuit;
means for traversing the circuit in a forward direction by traversing the network list of elements;
means for traversing the circuit in a backward direction by traversing the network list of elements; and
means for identifying a feedback loop in response to traversing the circuit in the forward direction and in response to traversing the circuit in the backward direction.

27. A test system comprising:
means for accessing an integrated circuit design represented as a network list of elements, the integrated circuit design comprising a controller including a port communicating with registers using a data stream;
means for identifying the controller from the network list of elements;
means for identifying the port driven by the test controller;
means for traversing the network list of elements;
means for generating a table of configuration information in response to traversing the network list of elements; and
means for identifying a configuration problem by querying the table of configuration information.
